(19) United States
(12) Patent Application Publication
(10) Pub. No.: US 2010/0123215 A1
(43) Pub. Date: May 20, 2010

(54) Capacitor Die Design for Small Form Factors

(75) Inventors: Yuancheng Christopher Pan, San Diego, CA (US); Fifin Sweeney, San Diego, CA (US); Charlie Paynter, La Jolla, CA (US); Kevin R. Bowles, Mission Viejo, CA (US); Jason R. Gonzalez, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/620,884

(22) Filed: Nov. 18, 2009

Related U.S. Application Data
(60) Provisional application No. 61/116,505, filed on Nov. 20, 2008.

(51) Int. Cl. H01L 23/52; H01L 21/50; H01L 23/498

(52) U.S. Cl. 257/532; 257/724; 438/121; 438/396; 257/E21.499; 257/E23.141; 257/E23.07

(57) ABSTRACT

A semiconductor package has a capacitor die and a packaging substrate. The capacitor die is coupled to circuitry on a front or back side of a die coupled to the packaging substrate for providing decoupling capacitance. In one example, the capacitor die is coupled to a land side of the packaging substrate in an area depopulated of a packaging array and adjacent to the packaging array. In another example, the capacitor die may be stacked on the die and coupled through wire bonds to circuitry on the die. The capacitor die reduces impedance of the integrated circuit allowing operation at higher frequencies.

### CROSS-REFERENCE TO RELATED APPLICATION

This application claims the benefit of U.S. Provisional Patent Application No. 61/116,505 filed on Nov. 20, 2008, in the names of Pan et al, and entitled “Capacitor Die Design for Small Form Factors.”

### TECHNICAL FIELD

The present disclosure generally relates to integrated circuits (ICs). More specifically, the present disclosure relates to packaging integrated circuits.

### BACKGROUND

Integrated circuits (ICs) are fabricated on wafers. Commonly, these wafers are semiconductor materials, for example, silicon. Through efforts of research and development, the size of the transistors making up the integrated circuits has decreased to 45 nm and soon will decrease further to 32 nm. As the transistors reduce in size, the voltage supplied to the transistors decreases. These voltages are commonly smaller than the wall voltages available in most countries.

An integrated circuit is commonly coupled to a voltage regulator that converts available wall voltages to the lower voltages used by the integrated circuit. The voltage regulator ensures a predictable power supply is provided to the integrated circuit. This is an important function, because the ability of transistors to tolerate voltages under or over the target voltage is small. Only tenths of a volt lower may create erratic results in the integrated circuits; only tenths of a volt higher may damage the integrated circuits.

As transistors of the integrated circuit turn on and off, the power load changes rapidly placing additional demand on the voltage regulator. The distance between the voltage regulator and the integrated circuit creates a long response time due to inductance in the wire or trace between the transistor and the voltage regulator. For example, in the case of a flip chip a conventional inductance may result in 3 nanoHenries.

The inductance prevents the voltage regulator from increasing power to the integrated circuit instantaneously, especially when the transistors switch on and off millions or billions of times each second. As the voltage regulators attempt to respond, ringing (or bouncing) may be occur. Decoupling capacitors provide additional stability to the power supplied to the integrated circuits.

Decoupling capacitors attached in close proximity to the integrated circuit provide a charge reservoir for the integrated circuit. As demand on the power supply changes rapidly, the capacitor provides additional power and can refill at a later time when the power demand decreases. The decoupling capacitor allows integrated circuits to operate at the high frequencies and computational speeds desired by consumers. However, as the transistor sizes have decreased and transistor densities increased, finding area on the integrated circuit for decoupling capacitors has become difficult.

One configuration of decoupling the integrated circuit places decoupling capacitors directly on the die. This configuration occupies die area that could otherwise be used for active circuitry. Additionally, fabricating these decoupling capacitors involves additional processes that increase the cost of manufacturing.

Conventionally, the decoupling capacitors are built from thick oxide transistors commonly used for I/O transistors. These capacitors are fabricated on the substrate to provide decoupling capacitance for the circuitry on the substrate. Thick oxide transistors offer very small values of capacitance in comparison to the large amounts of substrate area they consume that could otherwise be used for other circuitry.

A second configuration of decoupling the integrated circuit uses surface mount (SMT) capacitors on the land side of the packaging substrate. The land side of the packaging substrate is the side populated by connectors for coupling to external circuits. Thus, placing the surface mount capacitors on the land side does not consume active areas of the semiconductor die. However, the capacitors must be able to fit within the constrained height of the connectors. Surface mount capacitors are standard off-the-shelf parts, and their method of manufacturing limits the size of their manufacture. As packaging substrates reduce in size to match the size constraints of the devices they are integrated into, the connectors reduce in size proportionally and the surface mount capacitors become too large to fit on the land side.

Thus, there is a need for a method of providing decoupling to integrated circuits in a smaller package.

### BRIEF SUMMARY

According to one aspect of the disclosure, a semiconductor package includes a packaging substrate. The semiconductor package also includes a die attached to the packaging substrate through a packaging connection. The semiconductor package further includes a capacitor die coupled to a land side of the packaging substrate adjacent to the packaging connection. The capacitor die provides decoupling capacitance to a circuit on the die.

According to another aspect of the disclosure, a semiconductor package includes a packaging substrate having a first packaging connection. The semiconductor package also includes a die coupled to the packaging substrate through a second packaging connection. The semiconductor package also includes a capacitor die coupled to the die through a third packaging connection.

According to a further aspect of the disclosure, a semiconductor package includes a packaging substrate. The semiconductor package also includes a die having a first side opposing a second side. The first side faces the packaging substrate. The semiconductor package further includes a capacitor embedded in the second side of the die.

According to another aspect of the disclosure, a method of manufacturing a semiconductor package having a packaging substrate with connectors on a land side of the packaging substrate the method includes depopulating at least one of the connectors on the land side of the packaging substrate to create a depopulated region. The method also includes coupling a capacitor die in the depopulated region of the packaging substrate.

According to a further aspect of the disclosure, a semiconductor package includes a first packaged die having a first set of connectors. The semiconductor package also includes a second packaged die having a second set of connectors. The second packaged die is coupled to the first packaged die through the second set of connectors. The semiconductor package further includes a capacitor die disposed between the first packaged die and the second packaged die having a third set of connectors. The capacitor die is coupled to at least one of the first packaged die and the second packaged die.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a block diagram showing an exemplary wireless communication system in which an embodiment of the disclosure may be advantageously employed.

FIG. 2 is a cross-sectional view illustrating a packaged die having a capacitor die embedded in a packaging substrate.

FIG. 3 is a cross-sectional view illustrating a packaged die having a capacitor die coupled on a land side of the packaging substrate according to one embodiment of the disclosure.

FIG. 4 is a cross-sectional view illustrating a packaged die having an embedded die and a capacitor die coupled on a land side of the packaging substrate according to one embodiment of the enclosure.

FIG. 5 is a graph illustrating the impedance of a packaged product with and without a capacitor die coupled on the land side of a packaging substrate.

FIG. 6 is a cross-sectional view illustrating a package-on-package die having a capacitor die for decoupling according to one embodiment of the disclosure.

FIG. 7 is a block diagram illustrating a packaged integrated circuit utilizing flip chip assembly technology according to one embodiment.

FIG. 8 is a block diagram of a packaged integrated circuit utilizing wire bond assembly technology according to one embodiment.

### DETAILED DESCRIPTION

The integrated circuits discussed below allow placement of decoupling capacitors to reduce size of packaged products. These integrated circuits may be employed in wireless networks.

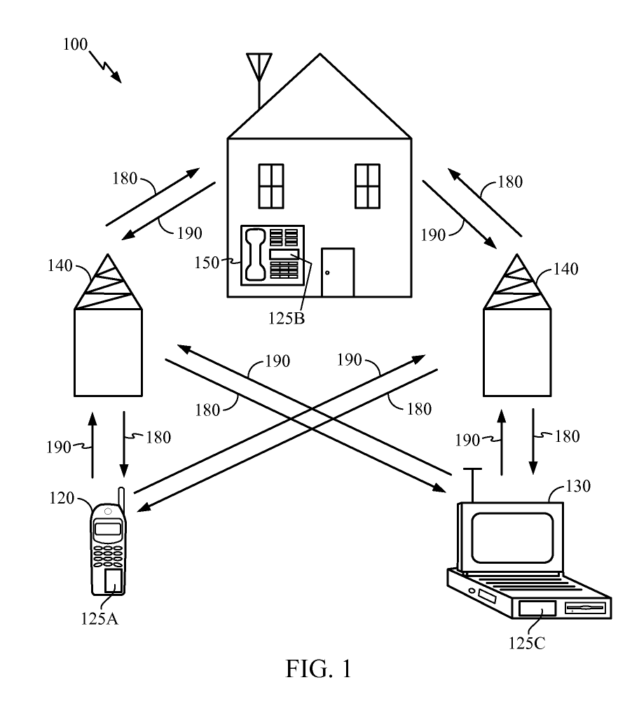

FIG. 1 is a block diagram showing an exemplary wireless communication system 100 in which an embodiment of the disclosure may be advantageously employed. For purposes of illustration, FIG. 1 shows three remote units 120, 130, and 150 and two base stations 140. It will be recognized that typical wireless communication systems may have many more remote units and base stations. Remote units 120, 130, and 150 include IC devices 125A, 125B and 125C, that include the disclosed packaging. It will be recognized that any device containing an IC may also include the circuitry disclosed here, including the base stations, switching devices, and network equipment. FIG. 1 shows forward link signals 180 from the base station 140 to the remote units 120, 130, and 150 and reverse link signals 190 from the remote units 120, 130, and 150 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 1 illustrates remote units according to the teachings of the disclosure, the disclosure is not limited to these exemplary illustrated units. The disclosure may be suitably employed in any device which includes integrated circuits packaged as described below.

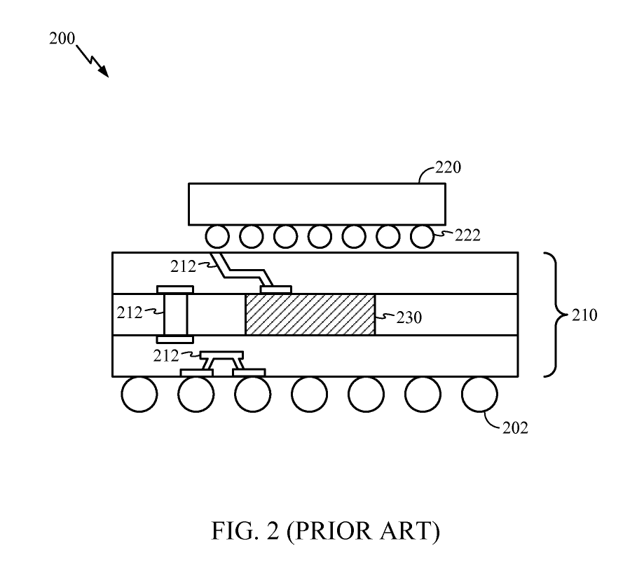

FIG. 2 is a cross-sectional view illustrating a conventional packaged die having a capacitor die embedded in a packaging substrate. A packaged die 200 includes a packaging substrate 210 and a semiconductor die 220. The semiconductor die 220 is attached to a front side of the packaging substrate 210 by ball grid array (BGA) packaging 222. Other methods of packaging may also be used to attach the semiconductor die 220 to the packaging substrate 210 such as pin grid array (PGA) or land grid array (LGA). The packaging substrate 210 also includes a ball grid array (BGA) packaging 202 to facilitate further processing. A capacitor die 230 is embedded in the packaging substrate 210 and used for decoupling of the semiconductor die 220. The packaging substrate 210 may also include a number of interconnects 212 to support various functions of the packaged die 200.

Embedding the capacitor die 230 in the packaging substrate 210 as conventionally implemented in FIG. 2 is a costly endeavor. Additional processes and materials are used to form the capacitor die and integrate it into the packaging substrate. An alternative and less costly solution is to place the capacitor die outside the packaging substrate on one of the sides. The packaging substrate 210 is only a few millimeters larger in area than the semiconductor die 220. In such an arrangement there is little space to place the capacitor die 230 on the same side of the packaging substrate 210 as the semiconductor die 220. Space may be found, however, on the land side of the packaging substrate. The land side refers to the side of the packaging substrate that includes packaging connections such as the ball grid array packaging 222. Placing capacitors on the land side is challenging because conventional capacitors have not decreased in size of a similar rate as packaging has decreased in size. Therefore, conventional capacitors do not fit in the constrained height of the packaging array.

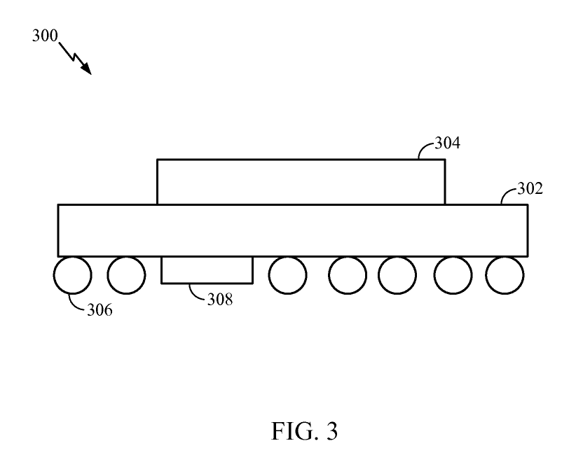

Turning now to FIG. 3, a cross-sectional view illustrating a packaged die having a capacitor die coupled on a land side of a packaging substrate according to one embodiment of the disclosure is presented. A integrated circuit die 304 is attached to a packaging substrate 302. A ball grid array (BGA) 306 is attached to the packaging substrate 302. Other methods of connectivity packaging may also be used such as pin grid array (PGA) or land grid array (LGA). A capacitor die 308 is coupled to the land side of the packaging substrate 302 in an area depopulated of the ball grid array 306. The capacitor die 308 is used to decouple the die 304 and includes a number of capacitors of various values for different power supply lines coupled to the packaging substrate 302. The capacitor die 308 may be, in one embodiment, of a thickness of less than 200 μm and smaller than the pitch of the ball grid array 306. Thus, the pitch of balls in the ball grid array 306 may be, in one embodiment, less than 0.5 mm. The capacitor die 308 may be manufactured thinner to support smaller pitches of the ball grid array 306.

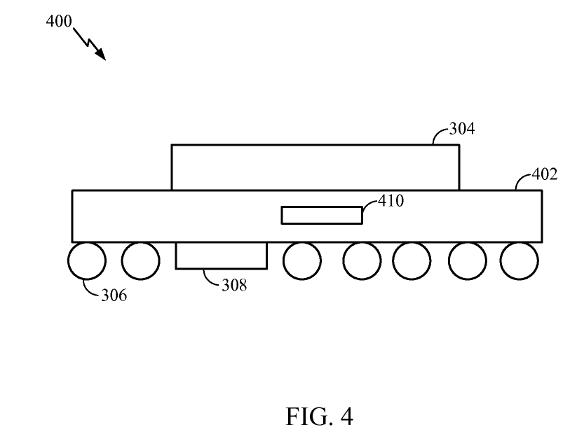

Another embodiment is shown in FIG. 4 where a cross-sectional view illustrates a packaged die having an embedded die and a capacitor die coupled on a land side of the packaging substrate. A packaged substrate 400 has a configuration similar to that of FIG. 3. However, additional circuitry is contained on a die 410 embedded in a packaging substrate 402. The packaging substrate 402 is referred to as an embedded die substrate (EDS).

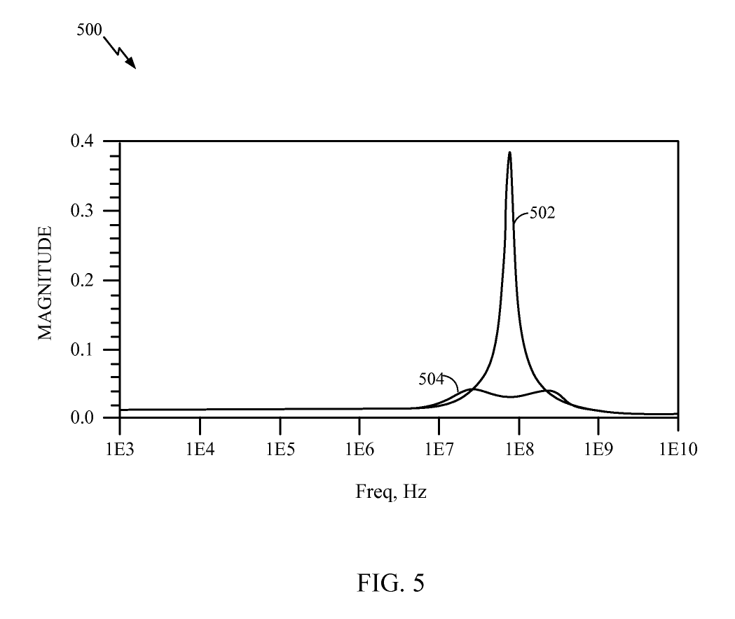

FIG. 5 is a graph illustrating the impedance of a packaged product with and without a capacitor die coupled on a land side of a packaging substrate. A graph 500 illustrates the magnitude of the impedance of the power supply versus operating frequency. Results displayed in the graph 500 are obtained from simulation with and without a 4 mm by 4 mm capacitor die placed directly under the processor on the land side of the package. The capacitor die provides a low-impedance current path and clean power supply free of noise to the semiconductor die attached to the capacitor die. Without the capacitor die, noise in the power supply leads to silicon failures and operating frequency degradations. A line 502 illustrates impedance of the processor without a capacitor die. A large peak in impedance of the power supply is observed around 1×10⁸ Hertz. A line 504 illustrates impedance of the same processor with a 4 mm by 4 mm capacitor die. Impedance is reduced by a factor of ten in this configuration.

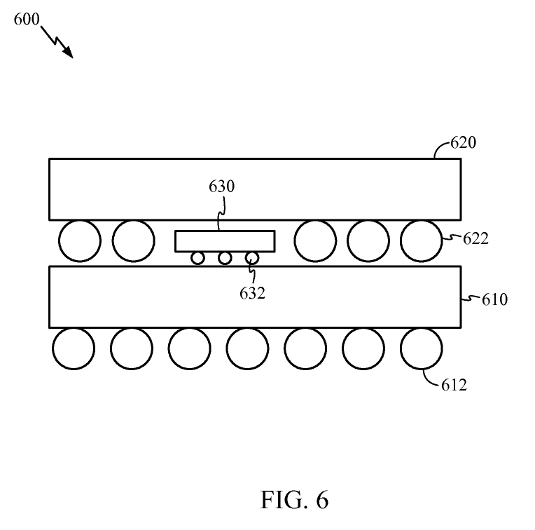

Turning now to FIG. 6, a cross-sectional view illustrating a package-on-package die having a capacitor die for decoupling according to one embodiment of the disclosure is presented. A first packaged die 620 is coupled to a second packaged die 610 through a ball grid array (BGA) packaging 622. Other methods of packaging may also be used such as a pin grid array (PGA) or a land grid array (LGA). The second packaged die 610 also includes a ball grid array (BGA) packaging 612 to facilitate coupling to external circuits. A capacitor die 630 is coupled to the second packaged die 610, in an area depopulated of a fraction of the ball grid array packaging 622, through a ball grid array (BGA) packaging 632. The capacitor die 630 may also be coupled to the first packaged die 620 alternatively or additionally. The capacitor die 630 provides decoupling for the second packaged die 610. The first packaged die 620 and the second packaged die 610 may both include an embedded die as illustrated in FIG. 4.

A capacitor die when placed on the land side of a packaging substrate enhances performance of attached integrated circuits by reducing impedance. The form factor of the capacitor die allows it to be attached on the land side of a packaging substrate while allowing the packaged product to decrease in size. Additionally, placing a capacitor die on the land side reduces manufacturing costs compared to embedding the capacitor die or placing decoupling capacitors on the active side of the semiconductor die.

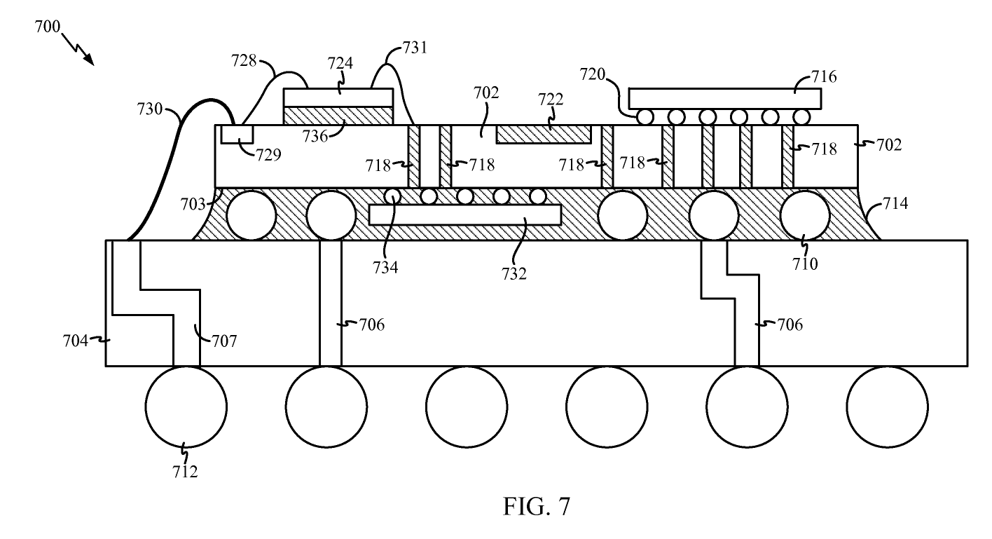

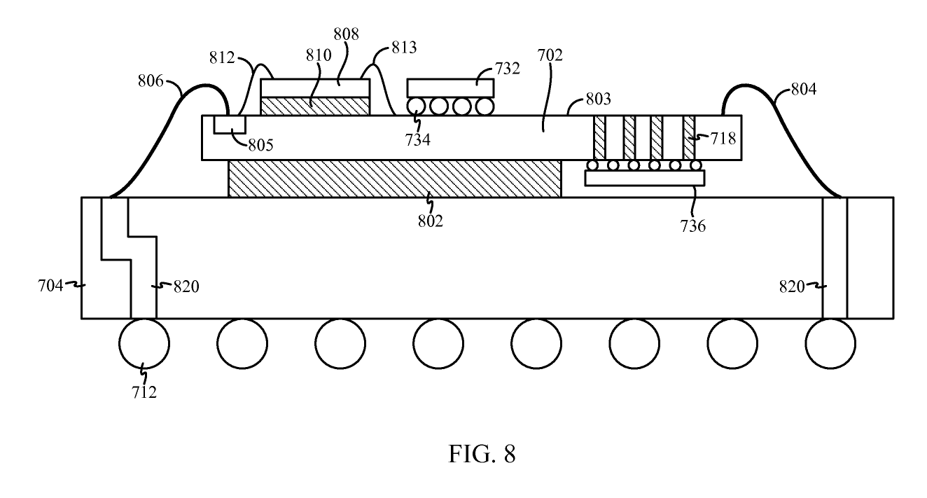

A capacitor die may be mounted on other locations on an integrated circuit. Turning now to FIGS. 7 and 8, additional embodiments of a low profile decoupling capacitor will be described utilizing flip chip assembly and wire bond assembly.

FIG. 7 is a block diagram illustrating a packaged integrated circuit utilizing flip chip assembly technology according to one embodiment. A stacked IC 700 includes a die 702 coupled to a packaging substrate 704 and may be, for example, a semiconductor die. In flip chip assembly, circuitry (not shown) is on a side 703 of the die 702 facing towards the packaging substrate 704.

An interface connection 710, such as bumps or pillars, couple the die 702 to the packaging substrate 704. According to one embodiment, the interface connection 710 may also be solder fabricated by the Controlled Collapse Chip Connection (C4) evaporative bump process.

Through vias 706 in the packaging substrate 704 may couple the interface connection 710 to the packaging connection 712. Additionally, pads and under bump metallization layers (not shown) may be present. The packaging connection 712 may be, for example, pins or solder balls. An underfill 714 is applied between the die 702 and the packaging substrate 704.

The die 702 includes through silicon vias 718. The through silicon vias 718 may extend an entire height of the die 702 and enable communication between sides of the die 702. According to one embodiment, a fraction of the through silicon vias 718 are coupled to a ground rail, and another fraction of the through silicon vias 718 are coupled to a power rail. Yet another fraction of the through silicon vias 718 are connected to interconnects or components on the integrated circuit other than a power or ground rail, such as for input/output (I/O) communications.

Several decoupling capacitors are coupled to the die 702 and will be described in further detail below. Although illustrated in combination, only one or more may be implemented in the stacked IC 700.

According to one embodiment, a decoupling capacitor 716 is stacked above the die 702. The decoupling capacitor 716 is coupled to the die 702 through an interconnect structure 720. The decoupling capacitor 716 provides decoupling capacitance to circuitry (not shown) on the side 703 of the die 702 with the through silicon vias 718. The decoupling capacitor 716 may be a die separate (discrete) from the die 702.

According to a second embodiment, a decoupling capacitor 724 may be placed on the die 702 using wire bonds. The decoupling capacitor 724 may be a discrete capacitor and is coupled to the die 702 with a die attach 736. Wire bonds 728, 730 are coupled through a conducting pad 729 and provide electrical coupling between the decoupling capacitor 724 and a through via 707 in the packaging substrate 704. The wire bonds 728, 730 enable communications between the decoupling capacitor 724 and the packaging connection 712. A wire bond 731 provides electrical coupling between the decoupling capacitor 724 and the through silicon vias 718. In one embodiment, a supply voltage may be provided to the decoupling capacitor 724 with the through via 707, wire bond 730, and wire bond 728. A regulated voltage may be provided to circuitry on the side 703 of the die 702 with the wire bond 731 and the through silicon via 718. According to another embodiment, the wire bond 730 is absent and the decoupling capacitor 724 is coupled with the die 702.

According to a third embodiment, a capacitor is integrated into the die 702. For example, a decoupling capacitor 722 is integrated on the die 702. In one case, metallization layers (not shown) couple the decoupling capacitor 722 to the through silicon vias 718. The decoupling capacitor 722 may be formed, for example, from transistors or alternating metal layers and dielectric layers on the die 702. In one embodiment, a transistor is used and the source and drain are coupled together to serve as one terminal of the capacitor, and the gate of the transistor serves as the second terminal. In another embodiment, metal layers are deposited on the die 702 alternating with dielectric material to form a parallel plate capacitor. The metal layers can be manufactured during the normal back end of line metal layer processing.

According to a fourth embodiment, a decoupling capacitor 732 is placed below the die 702. The decoupling capacitor 732 is disposed between the die 702 and the packaging substrate 704. The decoupling capacitor 732 is a discrete capacitor and may be coupled to the die 702 through an interconnect structure 734. After depopulating some of the interface connections 710, the decoupling capacitor 732 is attached to the die 702 prior to attaching the die 702 to the packaging substrate 704. In one embodiment, the interconnect structure has a height of 80 microns and the decoupling capacitor 732 is back grinded, resulting in a height of 50 microns. According to one embodiment, the underfill 714 is applied to the interconnect structure 734. In this embodiment, the decoupling capacitor does not increase the overall height of the packaged system.

Although several types of decoupling capacitors are illustrated in FIG. 7, any combination of the decoupling capacitors 724, 722, 732, and 716 may provide decoupling capacitance to the die 702, including only a single type of decoupling capacitor.

FIG. 8 is a block diagram of a packaged integrated circuit utilizing wire bond assembly technology according to one embodiment. In the embodiment of FIG. 8, the die 702 is attached to the packaging substrate 704 by a die attach 802, and communication between the die 702 and the packaging substrate 704 is enabled through wire bonds 804, 806. In wire bond assembly, circuitry (not shown) is on a side 803 of the die 702 facing away from the packaging substrate 704.

A decoupling capacitor 808 is coupled to the die 702 by a die attach 810, and communicates with the die 702 and the packaging substrate 704 by wire bonds 812, 813. The wire bond 813 may couple the decoupling capacitor 808 to circuitry (not shown) on the die 702. The wire bond 812 may couple on a conducting pad 805 to the a wire bond 806 coupled to the packaging substrate 704. Thus, an electrical path from the decoupling capacitor 808 to the packaging connection 712 is completed through the wire bonds 812, 806 and through vias 820 in the packaging substrate 704.

Each of decoupling capacitors 716, 722, 724, 732, and 808 may be a different type of capacitor. For example, a decoupling capacitor may include one or more co-planar metallic structures with interlaced digits. In another example, a decoupling capacitor may include a MOSFET (Metal Oxide Semiconductor Field Effect Transistor) in which a source and drain of the MOSFET are coupled to one another to form one plate of the decoupling capacitor, and the gate of the MOSFET serves as the other plate.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The semiconductor packages and integrated circuits described herein may contain, in part, memory circuits configured as memory devices, logic circuits configured as microprocessors, or other arrangements of circuitry. The circuitry may be used to support communications devices such as mobile handsets or base stations.

Although specific circuitry has been set forth, it will be appreciated by those skilled in the art that not all of the disclosed circuitry is required to practice the disclosure. Moreover, certain well known circuits have not been described, to maintain focus on the disclosure.

Although the terminology “through silicon via” includes the word silicon, it is noted that through silicon vias are not necessarily constructed in silicon. Rather, the material can be any device substrate material.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor package, comprising:
a packaging substrate;
a die attached to the packaging substrate through a packaging connection; and
a capacitor die coupled to a land side of the packaging substrate adjacent to the packaging connection, the capacitor die providing decoupling capacitance to a circuit on the die.

2. The semiconductor package of claim 1, in which the packaging connection comprises a plurality of balls of a ball grid array.

3. The semiconductor package of claim 2, in which the capacitor die is located in a region of the packaging connection depopulated of a fraction of the plurality of balls.

4. The semiconductor package of claim 3, in which a pitch of the packaging connection is less than 0.5 millimeters, and a thickness of the capacitor die is less than 200 micrometers.

5. The semiconductor package of claim 1, in which the semiconductor package is integrated into at least one of a cell phone, a hand-held personal communication systems (PCS) unit, a portable data unit, and a fixed location data unit.

6. A semiconductor package, comprising:
a packaging substrate having a first packaging connection;
a die coupled to the packaging substrate through a second packaging connection; and
a capacitor die coupled to the die through a third packaging connection.

7. The semiconductor package of claim 6, in which the capacitor die is adjacent to the second packaging connection and coupled to circuitry on a side of the die facing the packaging substrate.

8. The semiconductor package of claim 7, in which the second packaging connection is a plurality of balls of a ball grid array, and the capacitor die is located in a region depopulated of a fraction of the plurality of balls.

9. The semiconductor package of claim 6, and further comprising:
a first plurality of wire bonds coupling the capacitor die to the die; and
a second plurality of wire bonds coupling the first plurality of wire bonds to the packaging substrate, in which the third packaging connection is a die attach.

10. The semiconductor package of claim 9, further comprising:
a plurality of through silicon vias in the die coupled to circuitry on a side of the die facing the packaging substrate; and
a third plurality of wire bonds coupling the capacitor die to the plurality of through silicon vias.

11. The semiconductor package of claim 9, further comprising a third plurality of wire bonds coupling the capacitor die to circuitry on a side of the die facing away from the packaging substrate.

12. The semiconductor package of claim 6, further comprising a plurality of through silicon vias in the die, in which the capacitor die is attached on a side of the die facing away from the packaging substrate and coupled to circuitry on a side of the die facing the packaging substrate with the plurality of through silicon vias.

13. The semiconductor package of claim 6, further comprising a plurality of through silicon vias in the die, in which the capacitor die is adjacent to the second packaging connection and coupled to circuitry on a side of the die facing away from the packaging substrate with the plurality of through silicon vias.

14. A semiconductor package, comprising:
a packaging substrate;
a die having a first side opposing a second side, the first side facing the packaging substrate; and
a capacitor embedded in the second side of the die.

15. The semiconductor package of claim 14, in which the capacitor provides decoupling capacitance to the die.

16. A method of manufacturing a semiconductor package having a packaging substrate with connectors on a land side of the packaging substrate the method comprising:
depopulating at least one of the connectors on the land side of the packaging substrate to create a depopulated region; and
coupling a capacitor die in the depopulated region of the packaging substrate.

17. The method of claim 16, in which depopulating the connectors comprises depopulating balls of a ball grid array.

18. A semiconductor package, comprising:
a first packaged die having a first set of connectors;
a second packaged die having a second set of connectors, in which the second packaged die is coupled to the first packaged die through the second set of connectors; and
a capacitor die disposed between the first packaged die and the second packaged die having a third set of connectors, the capacitor die coupled to at least one of the first packaged die and the second packaged die.

19. The semiconductor package of claim 18, in which at least one of the first set of connectors, the second set of connectors, and the third set of connectors comprises a plurality of balls of a ball grid array.

20. The semiconductor package of claim 18, in which the semiconductor package is integrated into at least one of a cell phone, a hand-held personal communication systems (PCS) unit, a portable data unit, and a fixed location data unit.
